(19) United States
(12) Patent Application Publication
(10) Pub. No.: US 2023/0010814 A1
(43) Pub. Date: Jan. 12, 2023

(54) CREATING STAGING IN BACKPLANE FOR MICRO DEVICE INTEGRATION

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 17/781,972

(22) PCT Filed: Dec. 2, 2020
(86) PCT No.: PCT/CA2020/051648

§ 371 Date: Jun. 2, 2022

Related U.S. Application Data
(60) Provisional application No. 62/942,616, filed on Dec. 2, 2019.

(51) Int. Cl. H01L 23/00; H01L 27/12

(52) U.S. Cl. CPC H01L 24/05; H01L 27/124; H01L 2224/05572

(57) ABSTRACT

This disclosure is related to arranging to a system comprising of backplane and micro-devices. The backplane components layers may comprise of multiple conductive layers and multiple dielectric or semiconductor layers. The system is a stacked structure The stacking structure can be used with different types of transistors and backplane including but not limited to staggered, inverted staggered, and other types In addition, touch sensing structure can be integrated into the system.

### FIELD OF THE INVENTION

The present disclosure relates to the integration of circuits and systems into a micro-device substrate.

### BRIEF SUMMARY

A few embodiments of this description are related to integration of circuits and systems in micro-device substrate. The micro-device substrate may comprise micro light emitting diodes (LEDs), Organic LEDs, sensors, solid state devices, integrated circuits, (micro-electro-mechanical systems) MEMS, and/or other electronic components.

### BRIEF DESCRIPTION OF THE DRAWINGS

The foregoing and other advantages of the disclosure will become apparent upon reading the following detailed description and upon reference to the drawings.

FIG. 1 shows a stacked structure of backplane on a buffer layer.

FIG. 2A shows a stacked structure of backplane components on a buffer layer with additional layers and a pad connecting to the backplane.

FIG. 2B shows a stacked structure of backplane components on a buffer layer with additional layers, a pad connecting to the backplane and an additional layer creating a substrate for the backplane.

### DETAILED DESCRIPTION

One method to improve the system performance is to integrate microdevices into a system substrate. The challenge is to transfer millions of these devices and integrate them with circuits for every pixel with proper yield.

In one embodiment, integrated circuit and system is integrated on top of micro-devices transferred to a substrate. Here, there are openings in a planarization layer (or layers) to connect the micro-devices with the circuits.

In one embodiment, light reflectors can be used to redirect the light.

In another embodiment, color conversion layer or color filters are integrated before the micro-devices on the substrate surface opposite to the surface of micro-devices.

In this disclosure, pads in a receiver substrate refers to a designated area in receiver substrate to where a micro device is transferred. The pads could be conducive to prepare connection between the micro device and the pixel circuits or connections where the pixel circuits can be underneath the pad or on the side of the pad. The pad could have some form of bonding materials to hold the micro device permanently. The pad can be a stack of multi-layer to offer more mechanically stable structure and also better functions such as bonding and conductivity capability.

The following applies to any embodiment: The pads in this description can either provide an electrical connection, or a mechanical connection or just a defined area for transferring micro devices. The shape of pads used in the embodiments are for the purpose of illustration and the pads can have any arbitrary shape. The position of pads in respect to the pixels can be changed without any effect on any of the embodiments. The orientation of the group of pads in the pixel can be changed. For example, they can be rotated, shifted or moved to a different position. The pads can have complex structure comprising of different conductive, semiconductor and dielectric layers. The pads can be positioned on top of other structures such as transistors in the receiver substrate. Also, the pads can be besides other structures on the receiver substrate.

The following applies to any embodiment: The shape of light source devices used in the embodiments are for the purpose of illustration and these devices can have different shapes. The light source devices can have one or more pads on the side that will contact the receiver substrate. The pads can be mechanical, electrical or a combination of both. The one or more pads can be connected to a common electrode or row/column electrodes. The electrodes can be transparent or opaque. The light sources can have different layers. The light sources can be made of different materials such as organic, inorganic, or combination of them.

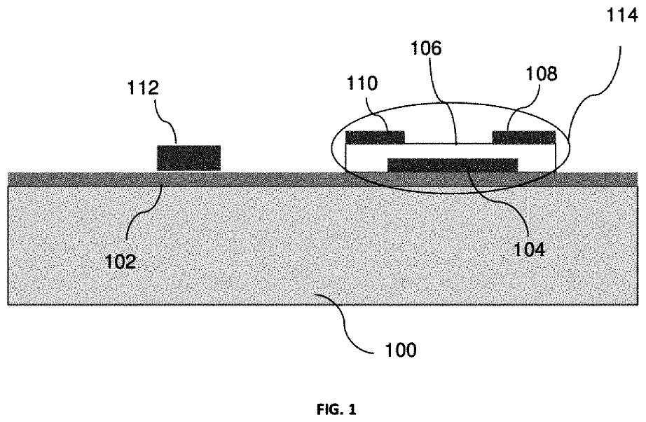

FIG. 1 shows a substrate 100. A buffer layer 102 can be deposited on top of the substrate 100. This buffer layer (or layers) can be used as delamination layer as well separating the fully integrated system from the substrate 100. It is possible to eliminate the layer 102 especially when the stacked micro-device and circuit structure is staying on the substrate 100. The backplane components can form on top of the substrate 100 or buffer layer 102. The backplane components may include multiple conductive layers 104, 110 and 108 and multiple dielectric or semiconductor layers 106. In one case, one conductive layer can be patterned to form electrodes and gate electrode 104 for a transistor 114. Stack of dielectric and semiconductor layers, that are part of the backplane, can form the channel of the transistors and source and drain region. After that, other electrode layers can form to create a connection to source and drain region and other signal types. Also, a pad 112 can form to connect a microdevice to the backplane. One of the transistors 114 on the backplane can be coupled to the pad 112. As can be seen the pad 112 can have lower profile compared to the other part of the backplane. To compensate for that and eliminate interference from the areas with higher profile on the backplane with micro-device integration into the backplane, the pad 112 should be taller than the highest profile of the backplane.

The stacking structure described in FIG. 1 can be used with different types of transistors and backplane including but not limited to staggered, inverted staggered, and other types. It can be also used with metal oxide, LTPS, Amorphous silicon, organic, and other type of backplane materials.

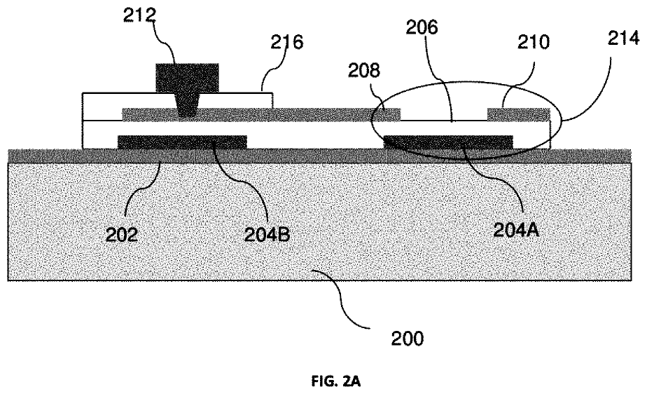

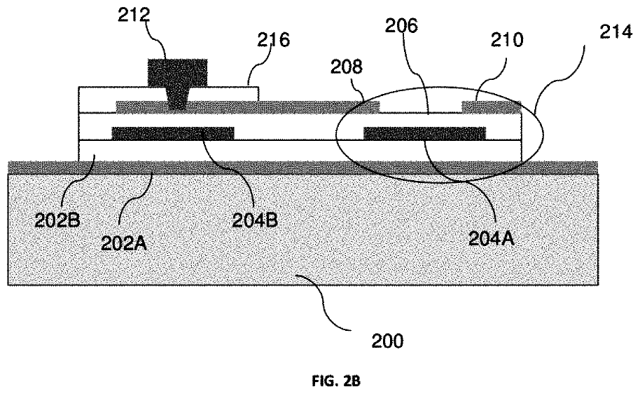

FIG. 2A shows a substrate 200. A buffer layer 202 can be deposited on top of the substrate 200. This buffer layer (or layers) can be used as delamination layer as well separating the fully integrated system from the substrate 200. It is possible to eliminate this layer 202 specially when the stacked micro-device and circuit structure is staying on the substrate 200. The backplane components can form on top of the substrate 200 or buffer layer 202. The backplane may include multiple conductive layers 204A, 210 and 208 and multiple dielectric or semiconductor layers 206, 216. In one case, one conductive layer can be patterned to form electrodes and gate electrode 204A for a transistor. Stack of dielectric and semiconductor layers can form the channel of the transistors and source and drain region. After that, other electrode layers can form to create the connection to source and drain region and other signal types. Also, a pad 212 can form to connect a microdevice to the backplane. One of the transistors on the backplane can be coupled to the pad 212. Here, different layers of the backplane 204B, 206, 208 and 216 are also formed and stack under the pad 212. These layers can be part of active electrodes or devices or just dummy layers. In one case, the conductive layer 208 can be extended to couple the transistor 214 to the pad 212. The stacked layers underneath the pad 212, provide the highest profile surface on the substrate and as such eliminating any interference from the backplane during the micro device transfer.

The stacking structure described in FIG. 2 can be used with different types of transistors and backplane including but not limited to staggered, inverted staggered, and other types. It can be also used with metal oxide, LTPS, Amorphous silicon, organic, and other type of backplane materials.

FIG. 2B shows a substrate 200. A buffer layer 202A can be deposited on top of the substrate 200. This buffer layer (or layers) can be used as delamination layer as well separating the fully integrated system from the substrate 200. It is possible to eliminate this layer 202 specially when the stacked micro-device and circuit structure is staying on the substrate 200. Another layer 202B can form on top of the buffer layer(s) to create a substrate for the backplane after the delamination. The backplane components can form on top of the substrate 200 or buffer layer 202. The backplane may include multiple conductive layers 204A, 210 and 208 and multiple dielectric or semiconductor layers 206 and 216. In one case, one conductive layer can be patterned to form electrodes and gate electrode 204A for a transistor 214. Stack of dielectric and semiconductor layers in the backplane can form the channel of the transistors and source and drain region. After that, other electrode layers can form to create the connection to source and drain region and other signal types. Also, a pad 212 can be formed to connect a microdevice to the backplane. One of the transistors 214 on the backplane can be coupled to the pad 212. Here, different layers of the backplane 204B, 206, 208 and 216 are also formed and stacked under the pad 212. These layers can be part of active electrodes or devices or just dummy layers. In one case, the conductive layer 208 can be extended to couple the transistor to the pad 212. The stacked layers underneath the pad 212, provide the highest profile surface on the substrate and as such eliminating any interference from the backplane during the micro device transfer.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of the invention as defined by the appended claims.

What is claimed is:

1. A stacked structure, the stacked structure comprising:
a pad; and
backplane components layers comprising of multiple conductive layers and multiple dielectric or semiconductor layers, wherein the pad is taller than a highest profile of any of the backplane components.

2. The structure of claim 1, wherein one of the conductive layers is patterned to form electrodes and a gate electrode for a transistor.

3. The structure of claim 1, wherein one of a transistor electrodes is extended to couple with the pad.

4. The structure of claim 3, wherein part of the backplane, forms a channel of the transistor and a source and a drain region.

5. The structure of claim 4, wherein electrode layers create a connection to the source and the drain region and other signal types.

6. The structure of claim 1, wherein the pad is connected to a microdevice.

7. The structure of claim 1, wherein the backplane components form on top of a buffer layer deposited on top of a substrate.

8. The structure of claim 1, wherein the buffer layer is used as a delamination layer as well as separating a fully integrated system from the substrate.

9. The structure of claim 8, wherein an additional layer forms on top of the buffer layer to create a second substrate for the backplane after a delamination.

10. A method to eliminate interference using a stacked structure, the method comprising:
having a backplane with components layers comprising of multiple conductive layers and multiple dielectric or semiconductor layers; and
having a pad taller than a highest profile of any of the backplane components.

11. The method of claim 10, wherein one of the conductive layers is patterned to form electrodes and gate electrode for a transistor.

12. The method of claim 10, wherein one of a transistor electrodes is extended to couple with the pad.

13. The method of claim 12, wherein a part of the backplane, forms a channel of the transistor and a source and a drain region.

14. The method of claim 13, wherein electrode layers create a connection to the source and the drain region and other signal types.

15. The structure of claim 10, wherein the pad is connected to a microdevice.

16. The method of claim 10, wherein the backplane components form on top of a buffer layer deposited on top of a substrate.

17. The method of claim 10, wherein the buffer layer is used as a delamination layer as well as separating a fully integrated system from the substrate.

18. The method of claim 17, wherein an additional layer forms on top of the buffer layer to create another substrate for the backplane after a delamination.

What is claimed is:

1. A stacked structure, the stacked structure comprising:
a pad; and
backplane components layers comprising of multiple conductive layers and multiple dielectric or semiconductor layers, wherein the pad is taller than a highest profile of any of the backplane components.

2. The structure of claim 1, wherein a conductive layer can be patterned to form electrodes and a gate electrode for a transistor.

3. The structure of claim 1, wherein one of a transistor electrodes can be extended to couple with the pad.

4. The structure of claim 3, wherein part of the backplane, can form a channel of the transistor and a source and a drain region.

5. The structure of claim 4, wherein electrode layers create a connection to the source and the drain region and other signal types.

6. The structure of claim 1, wherein the pad is connected to a microdevice.

7. The structure of claim 1, wherein the backplane components can form on top of a buffer layer deposited on top of a substrate.

8. The structure of claim 1, wherein the buffer layer can be used as a delamination layer as well as separating the fully integrated system from the substrate.

9. The structure of claim 8, wherein an additional layer can form on top of the buffer layer to create a substrate for the backplane after a delamination.

10. A method to eliminate interference using a stacked structure, the method comprising:
having a backplane with components layers comprising of multiple conductive layers and multiple dielectric or semiconductor layers; and
having a pad taller than a highest profile of any of the backplane components.

11. The method of claim 10, wherein a conductive layer can be patterned to form electrodes and gate electrode for a transistor.

12. The method of claim 10, wherein one of a transistor electrodes can be extended to couple with the pad.

13. The method of claim 12, wherein part of the backplane, can form the channel of the transistor and a source and a drain region.

14. The method of claim 13, wherein electrode layers create a connection to the source and the drain region and other signal types.

15. The structure of claim 10, wherein the pad is connected to a microdevice.

16. The method of claim 10, wherein the backplane components can form on top of a buffer layer deposited on top of a substrate.

17. The method of claim 10, wherein the buffer layer can be used as a delamination layer as well as separating the fully integrated system from the substrate.

18. The method of claim 17, wherein an additional layer can form on top of the buffer layer to create a substrate for the backplane after a delamination.
